(19) United States
(12) Patent Application Publication
(10) Pub. No.: US 2026/0314450 A1
(43) Pub. Date: Oct. 8, 2026

(54) MODULE STRUCTURE

(71) Applicant: PanelSemi Corporation, New Taipei City (TW)

(72) Inventors: Chin-Tang LI, New Taipei City (TW); Jeng-Long SHEU, New Taipei City (TW)

(21) Appl. No.: 19/637,280

(22) Filed: Apr. 2, 2026

Related U.S. Application Data
(60) Provisional application No. 63/782,153, filed on Apr. 2, 2025.

(51) Int. Cl. H10W 70/65

(52) U.S. Cl. CPC H10W 70/65

(57) ABSTRACT

A module structure includes a substrate, a patterned stack structure, a patterned adhesive layer, and a semiconductor component. The substrate defines a first surface and a second surface. The patterned stack structure, arranged on the first surface of the substrate, includes one or both of a patterned optical layer and a patterned conductive layer for transmitting either one or both of optical signals and electrical signals. The patterned adhesive layer is arranged between the substrate and the patterned stack structure. The semiconductor component is arranged on the first surface of the substrate and coupled to the patterned adhesive layer, and the semiconductor component, the patterned adhesive layer and the patterned stack structure are arranged in a coplanar manner. The module structure can reduce the covering area of a signal transmission layer on the substrate, thereby improving the utilization rate of substrate surface and reducing signal loss.

### CROSS REFERENCE TO RELATED APPLICATIONS

This Non-provisional application claims priority to U.S. provisional patent application with Ser. No. 63/782,153 filed on Apr. 2, 2025. This and all other extrinsic materials discussed herein are incorporated by reference in their entirety.

### BACKGROUND

### Technology Field

The disclosure relates to relates to a module structure, particularly to a module structure with optical paths.

### Description of Related Art

As requirements for data exchange between optoelectronic modules and external devices is increased, the traditional electrical signal transmission interfaces face have reached a bottlenecks including limitations in transmission speed, electromagnetic interference issues, and high power consumption. Consequently, optical communication is chosen as an alternative solution by the industry. Optical communication has advantages such as high-speed signal transmission, strong interference resistance, and low power consumption. However, the technology for integrating optical communication into optoelectronic modules still faces numerous challenges, such as highly signal loss during transmission when the transmission distance is long. Therefore, a novel module structure featuring a simple design and ease of manufacturing, which can effectively shorten optical signal transmission path, is urgently need by the industry.

### SUMMARY

One aspect of this disclosure is to provide a module structure which can be incorporated into the existing module structures and effectively reduces a transmission distance of optical signal so as to significantly reduce optical signal loss.

This invention provides a module structure which comprises a substrate, a patterned stack structure, a patterned adhesive layer, and a semiconductor component. The substrate defines a first surface and a second surface opposite to each other. The patterned stack structure arranged on the first surface of the substrate, ex. arranged on at least a partial of the first surface; the patterned stack structure includes one or both of a patterned optical layer and a patterned conductive layer for transmitting either one or both of optical signals and electrical signals. The patterned adhesive layer is arranged between the substrate and the patterned stack structure. The semiconductor component is arranged on the first surface of the substrate and coupled to the patterned adhesive layer, and the semiconductor component, the patterned adhesive layer and the patterned stack structure are arranged in a coplanar manner.

This invention also provides a module structure which comprises a substrate, a patterned stack structure, a patterned adhesive layer, one or more vacant area, and a plurality of semiconductor components. The substrate defines a first surface and a second surface opposite to each other. The patterned stack structure arranged on the first surface of the substrate, ex. arranged on at least a partial of the first surface; the patterned stack structure includes one or both of a patterned optical layer and a patterned conductive layer for transmitting either one or both of optical signals and electrical signals. The patterned adhesive layer is arranged between the substrate and the patterned stack structure. The one or more vacant areas are arranged on the first surface at where the patterned stack structure is not arranged. The one or more semiconductor components are arranged on the first surface of the substrate and at the one or more vacant areas of the substrate, and coupled with the patterned stack structure. Further, the semiconductor components, and the patterned stack structure and the patterned adhesive layer are arranged in a coplanar manner. Two of the semiconductor components can communicate with each other by electrical signals and/or optical signals.

In one embodiment, the patterned stack structure defines a stack-structure contour which is defined by laser-cutting

In one embodiment, the patterned stack structure defines a stack-structure contour, the patterned adhesive layer defines an adhesive layer contour, and the adhesive layer contour approaches the stack-structure contour along a direction perpendicular to the first surface of the substrate.

In one embodiment, the adhesive layer contour is larger the stack-structure contour along a direction perpendicular to the first surface of the substrate.

In one embodiment, the patterned stack structure defines a coverage for the substrate which is not larger than 50%.

In one embodiment, the patterned adhesive layer defines a first adhesive layer surface and a second adhesive layer surface opposite to each other, the first adhesive layer surface connects to the patterned stack structure, and the second adhesive layer surface connects to the substrate; and a roughness of the first adhesive layer surface is smaller than a roughness of the second adhesive layer surface.

In one embodiment, the patterned stack structure comprises a base material, the patterned optical layer, the patterned conductive layer, or both are arranged on the substrate material.

In one embodiment, the base material comprises at least one of polyimide or resin material.

In one embodiment, the base material defines a coefficient of thermal expansion (CTE) less than 17 ppm along a direction parallel to the first surface of the substrate.

In one embodiment, the base material defines a coefficient of thermal expansion (CTE) less than 10 ppm along a direction parallel to the first surface of the substrate.

In one embodiment, the patterned stack structure comprises the patterned optical layer, and each of the patterned optical layer and the semiconductor component has an optical port for coupling each other.

In one embodiment, the patterned optical layer defines a first optical layer surface and a second optical layer surface opposite to each other, and a side edge connecting the first optical layer surface and the second optical layer surface, the optical port of the patterned optical layer is arranged at the side edge of the patterned optical layer.

In one embodiment, the patterned optical layer comprises an optical fiber which includes a core and a cladding layer surrounding the core; the core is aligned and optically coupled with the optical port of the semiconductor component

In one embodiment, the patterned optical layer comprises an optical waveguide which includes an optical transmission layer and a reflection layer arranged on at least one side of the optical transmission layer; the optical transmission layer is aligned and optically coupled with the optical port of the semiconductor component

In one embodiment, the first surface of the substrate is provided with a plurality of conductive pads, and the semiconductor component is electrically connected to the conductive pads.

In one embodiment, the semiconductor component comprises at least one of the electronic integrated circuit (EIC), photonic integrated circuit (PIC), graphics processing unit (GPU), central processing unit (CPU), application-specific integrated circuit (ASIC), switch.

In one embodiment, the module structure further comprises an interposer, and the semiconductor component is arranged in or on the interposer.

In one embodiment, the first surface of the substrate is provided with a plurality of conductive pads, and the interposer is electrically connected to the conductive pads

In one embodiment, the patterned stack structure comprises the patterned conductive layer, the patterned conductive layer comprises one or more layers of conductive traces, and at least a portion of the conductive traces has a trace space no greater than 50 μm.

In one embodiment, the patterned stack structure comprises the patterned conductive layer, the patterned conductive layer comprises one or more layers of conductive traces, and at least a portion of the conductive traces has a trace space no greater than 30 μm.

In one embodiment, the patterned stack structure comprises the patterned conductive layer, the patterned conductive layer comprises one or more layers of conductive traces, and at least a portion of the conductive traces has a trace space no greater than 15 μm

In one embodiment, the patterned stack structure comprises the patterned conductive layer, the patterned conductive layer comprises one or more layers of conductive traces, and at least a portion of the conductive traces has a thickness no greater than 20 μm.

In one embodiment, the patterned stack structure comprises the patterned conductive layer, the patterned conductive layer comprises one or more layers of conductive traces, and at least a portion of the conductive traces has a thickness no greater than 10 μm.

In one embodiment, the substrate comprises silica or silica-containing material.

In one embodiment, the substrate includes a single-layer or multi-layer substrate, and comprises glass, resin, ceramic, glass ceramic, polyimide, or comprising one or more above-mentioned materials.

In one embodiment, the substrate includes a single-layer or multi-layer substrate, and comprises bismaleimide triazine (BT), FR4 glass-reinforced epoxy laminate, or comprising one or more above-mentioned materials.

In one embodiment, the substrate includes at least one of a low-temperature co-fired ceramic (LTCC) substrate, a mid-temperature co-fired ceramic (MTCC) substrate, and a high-temperature co-fired ceramic (HTCC) substrate.

Accordingly, this invention utilizes a design of patterned stacked structure to arrange a pattered optical layer or a patterned conductive layer on a partial area on the substrate to transmit optical signal or electrical signal. This design can reduce the covering area of a signal transmission layer (or signal transmission structure) on the substrate, thereby improving the utilization rate of the substrate surface, which can reduce distance between the components and reduce signal loss due to long-distance transmission.

### BRIEF DESCRIPTION OF THE DRAWINGS

FIG. 1A and FIG. 1B are schematic diagrams showing a top view and a side view of one embodiment of this invention.

FIGS. 2 to 5, FIGS. 6A to 6C, and FIGS. 7 to 10 are schematic diagrams showing side views of different embodiments of this invention.

FIG. 11A to FIG. 11G are schematic diagrams showing a manufacturing method of this invention.

FIG. 12A and FIG. 12B are schematic diagrams showing top views of two temporary structures during manufacturing the module structure of this invention.

### DETAILED DESCRIPTION OF THE DISCLOSURE

The foregoing is merely illustrative and not intended to limit the disclosure. In addition to the illustrative embodiments, examples, and features described above, other embodiments, examples, and features of the disclosure can be clearly understood by referring to the drawings and the following detailed description.

The following description will refer to relevant drawings to explain the stacked substrate according to the preferred embodiments of this invention, wherein the same elements will be described using the same reference symbols.

The advantages, features, and implementation methods of this disclosure will be clearly explained in the following embodiments with reference to the drawings. However, this disclosure may be embodied in various forms and should not be construed as being limited to the embodiments described herein. Rather, these embodiments are provided to make this specification thorough and complete, and to fully convey the scope of the disclosure to those skilled in the art. The scope of this disclosure should be defined only by the appended claims. Therefore, well-known components, operations, and techniques are not described in detail in the embodiments to avoid obscuring the technical features of the disclosure. Throughout the specification, identical or similar elements are denoted by identical or similar reference symbols. When an element is referred to as being “connected” to another element, it may be “directly or indirectly mechanically connected” to, or “electrically connected” to the other element, and one or more intervening elements may be present therebetween. It is to be understood that in this specification, the terms “include” or “comprise” specify the stated features, integers, steps, operations, elements and/or components, but do not preclude the presence or addition of one or more other features, integers, steps, operations, elements and/or components, or any combination thereof. The term “and/or” or “or/and” indicates the possibility of intersection or union of one or more other features, integers, steps, operations, elements and components, or any combination thereof. Unless otherwise defined, all terms used in this specification (including technical and scientific terms) have the same meanings as commonly understood by those skilled in the art to which this disclosure pertains. Further, terms, including those defined in commonly used dictionaries, should be interpreted as having meanings consistent with their meaning in the context of the relevant art and will not be interpreted in an idealized or overly rigorous sense unless explicitly defined herein.

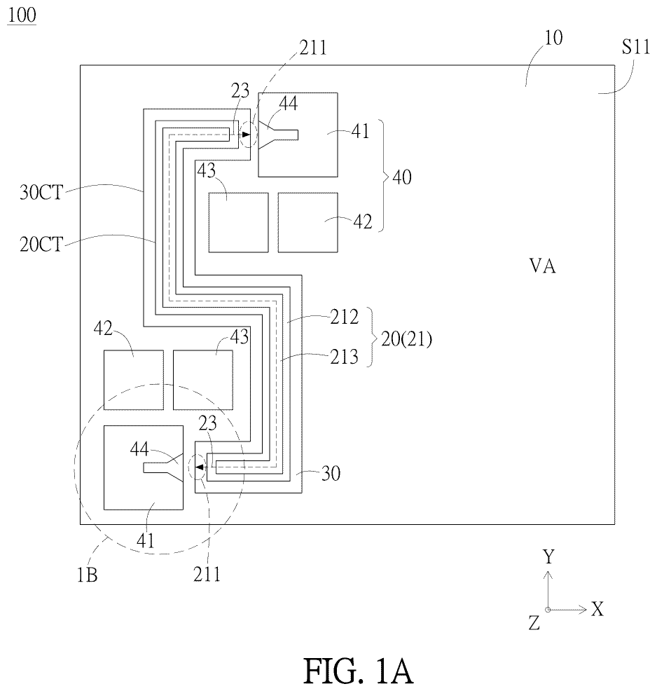

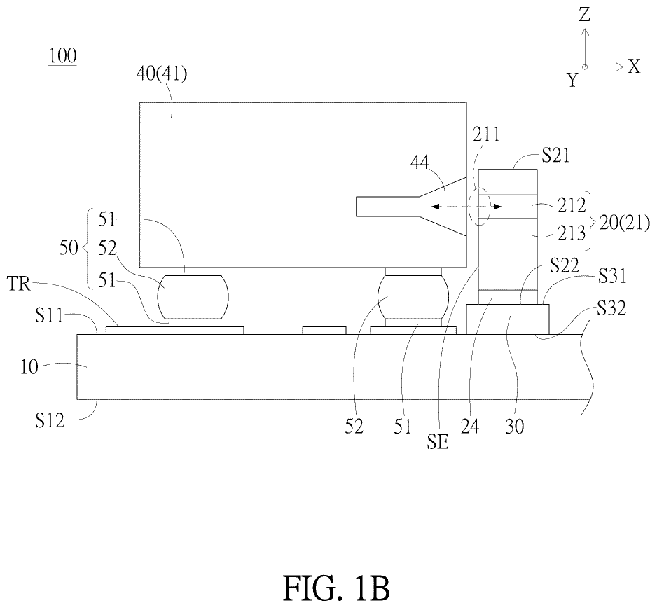

Referring to FIG. 1A and FIG. 1B, the module structure 100 of the present invention comprises: a substrate 10, a patterned stack structure 20, a patterned adhesive layer 30, and a semiconductor component 40.

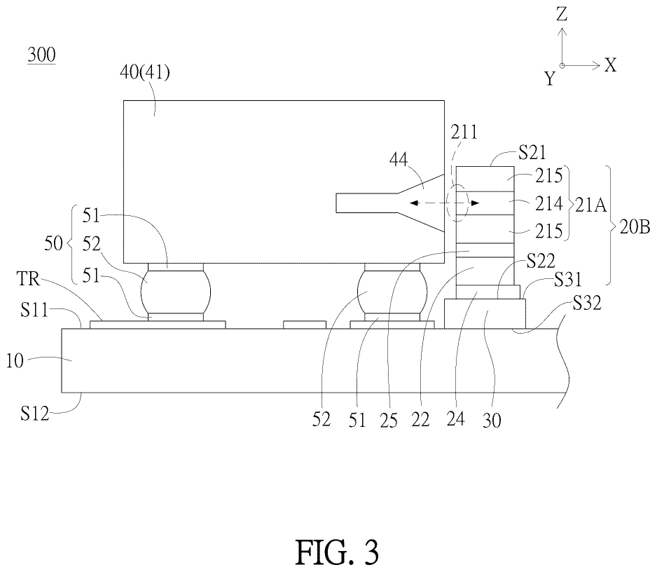

The substrate 10 defines a first surface S11 and a second surface S12 opposite to each other. The patterned stack structure 20 is arranged on the first surface S11 of the substrate, in this case, the patterned stack structure 20 is arranged on a partial of the first surface S11 of the substrate 10. The patterned stack structure 20 defines a first stack structure surface S21 and a second stack structure surface S22 opposite to each other, and the second stack structure surface S22 faces to the first surface S11 of the substrate 10. The patterned stack structure 20 includes one or both of a patterned optical layer 21 and a patterned conductive layer 22 (as shown in FIG. 3) for transmitting signal 23, the signal 23 comprises optical signals, electrical signals, or both. The patterned adhesive layer 30 is arranged between the substrate 10 and the patterned stack structure 20; wherein the patterned adhesive layer 30 defines a first adhesive layer surface S31 and a second adhesive layer surface S32 opposite to each other. The second adhesive layer surface S32 of the patterned adhesive layer 30 connects to the first surface S11 of the substrate 10, and the first adhesive layer surface S31 of the patterned adhesive layer 30 connects to the second stack structure surface S22 of the patterned stack structure 20. The semiconductor component 40 is arranged on the first surface S11 of the substrate 10 and coupled to the patterned stack structure 20, ex. the semiconductor component 40 is electrically and/or optically coupled to the patterned stack structure 20. In addition, the semiconductor component 40 is coplanar with the patterned adhesive layer 30 and the patterned stack structure 20 along a direction X parallel to the first surface S11 of the substrate 1.

In one embodiment, the substrate 10 includes a single-layer or multi-layer substrate, and comprises at least one material of silicon or silicon-containing material, glass, resin, ceramic, glass ceramic, polyimide, bismaleimide triazine (BT), or glass-reinforced epoxy laminate (FR4). Furthermore, the substrate 10 can also comprise at least one of a low-temperature co-fired ceramic (LTCC), a mid-temperature co-fired ceramic (MTCC), and a high-temperature co-fired ceramic (HTCC) substrate.

In one embodiment, the semiconductor component 40 includes at least one of an electronic integrated circuit (EIC), a photonic integrated circuit (PIC), a graphics processing unit (GPU), a central processing unit (CPU), an application-specific integrated circuit (ASIC), and a switch, but is not limited thereto. The semiconductor component 40 may further include passive components. Here, the semiconductor component 40 is exemplified as a photonic integrated circuit (PIC) 41.

The patterned stack structure 20 defines a stack-structure contour 20CT, the patterned adhesive layer 30 defines an adhesive-layer contour 30CT, and along a direction Z perpendicular to the first surface S11 of the substrate 10, a projection of the adhesive-layer contour 30CT approaches a projection of the stack-structure contour 20CT. However, in some cases, the projection of the adhesive-layer contour 30CT is larger than the projection of the stack-structure contour 20CT along the direction Z perpendicular to the first surface S11 of the substrate 10, but is not limited thereto.

The above-mentioned stack-structure contour 20CT or the adhesive-layer contour 30CT are formed by a laser cutting process. The contour can be a regular shape or an irregular shape; regular shape comprises shapes having a center of symmetry or an axis of symmetry, such as circles, squares, rectangles, trapezoids, rhombuses, etc. Irregular shapes include all other shapes besides regular shapes.

In some embodiments, the patterned stack structure 20 defines a coverage ratio to the substrate 10, and the coverage ratio is not greater than 50%. This indicated that when the patterned stack structure 20 is arranged on the first surface S11 of the substrate 10, the area of the first surface S11 covered by the patterned stack structure 20 is no greater than 50%.

In addition, a surface roughness of the first adhesive layer surface S31 of the patterned adhesive layer 30 is less than a surface roughness of the second adhesive layer surface S32.

Referring to FIG. 1B, the patterned stack structure 20 further includes a base material 24, and the patterned optical layer 21 and/or the patterned conductive layer 22 (as shown in FIG. 3) are arranged on the base material 24. The base material 24 includes at least one material of polyimide and resin, but is not limited.

Referring to FIG. 1A and FIG. 1B, the patterned stack structure 20 in this case includes the patterned optical layer 21, the patterned optical layer 21 has an optical port 211, and the semiconductor component 40 also has an optical ports 44, and the patterned optical layer 21 is optically coupled to the semiconductor component 40 by the optical ports 211, 44. In this case, the semiconductor component 40 is a photonic integrated circuit 41. As shown in FIG. 1B, the patterned optical layer 21 defines a side edge, two ends of the edge connects the first optical layer surface S211 and second optical layer surfaces S221, and the optical port 211 is arranged at the side edge of the patterned optical layer 21. The patterned optical layer 21 can be an optical fiber which includes a core 212 and a cladding layer 213 surrounding the core 212, wherein the optical port 211 of the core 212 is aligned and optically coupled with the optical port 44 of the semiconductor component 40.

Furthermore, as shown in FIG. 1B, on the first surface S11, the second surface of the substrate 10, or within the substrates, one or more circuit layer TR are provided. The semiconductor component 40 (41) can be electrically connected to the circuit layer TR by a conductive structure. In one embodiment, the conductive structure comprises conductive pads 51 and conductive materials 52. The conductive pads can be arranged on the first surface S11 of the substrate 10 and on a lateral of the semiconductor component 40 facing to the substrate 10, two conductive pads 51 are electrically connected by the conductive material 52 so as to electrically connect the semiconductor component 40 to the circuit layer T.

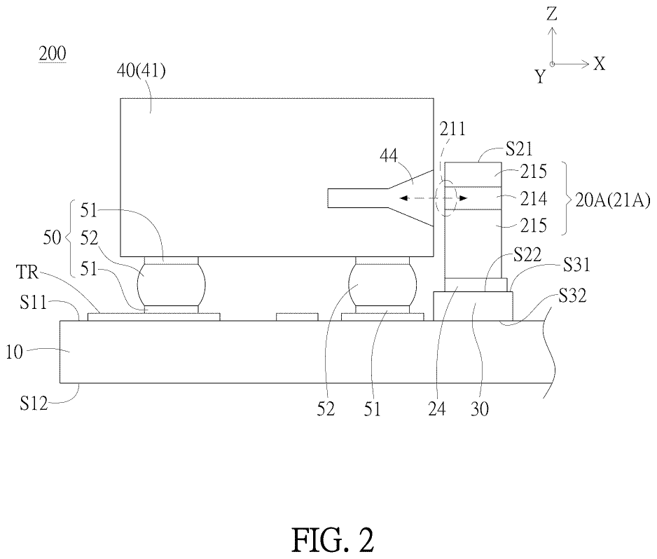

Referring to FIG. 2, the patterned stack structure 20A of the module structure 200 includes a patterned optical layer 21A, the patterned optical layer 21A, includes an optical waveguide comprising an optical transmission layer 214 and a reflection layer 215 disposed on at least one side of the optical transmission layer 214. The optical port 211 of the optical layer 21A is located at the optical transmission layer 214, and is aligned and optically coupled with the optical port 44 of the semiconductor component 40. In some cases, the reflection layer 215 of the patterned stack structure 20A can be integrated into the base material 24.

Referring to FIG. 3, the patterned stack structure 20B of the module structure 300 includes a patterned optical layer 21A and a patterned conductive layer 22. The patterned optical layer 21A includes an optical waveguide comprising an optical transmission layer 214 and a reflection layer 215 disposed on at least one side of the optical transmission layer 214, wherein the optical port 211 of the optical layer 21A is aligned and optically coupled with the optical port 44 of the semiconductor component 40. The patterned conductive layer 22 is arranged between the patterned optical layer 21A and the patterned adhesive layer 30. In FIG. 3, the patterned conductive layer 22 is exemplified as a single conductive layer, but is not limited. In addition, the patterned conductive layer 22 is bonded to the patterned optical layer 21A by an adhesive layer 25 in this case.

In some embodiments, when the patterned stack structure 20B, 20C, 20D, 20E, 20F includes the patterned conductive layer 22, the patterned conductive layer 22 may include one or more layers of conductive traces 221. At least a portion of the conductive traces 221 has a trace space no greater than 50 micrometers; or at least a portion of the conductive traces 211 has a trace space no greater than 30 micrometers; or at least a portion of the conductive traces 221 has a trace space no greater than 15 micrometers. In addition, at least a portion of the conductive traces 211 has a thickness no greater than 20 micrometers; or at least a portion of the conductive traces 221 has a thickness is no greater than 10 micrometers.

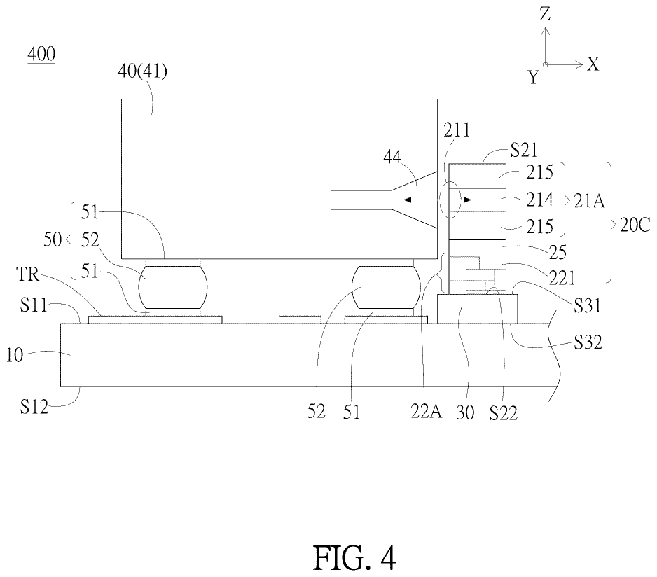

Referring to FIG. 4, the patterned stack structure 20C of the module structure 400 includes a patterned optical layer 21A and a patterned conductive layer 22A. The patterned optical layer 21A is an optical waveguide comprising an optical transmission layer 214 and a reflection layer 215 disposed on at least one side of the optical transmission layer 214, wherein the optical port 211 of the patterned optical layer 21A is aligned and optically coupled with the optical port 44 of the semiconductor component 40. The patterned conductive layer 22A is arranged between the patterned optical layer 21A and the patterned adhesive layer 30. In this case, the patterned conductive layer 22A is a multiple-layered conductive layer, ex. redistribution layers (RDL). In addition, the patterned conductive layer 22A in bonded to the patterned optical layer 21A by an adhesive layer 25.

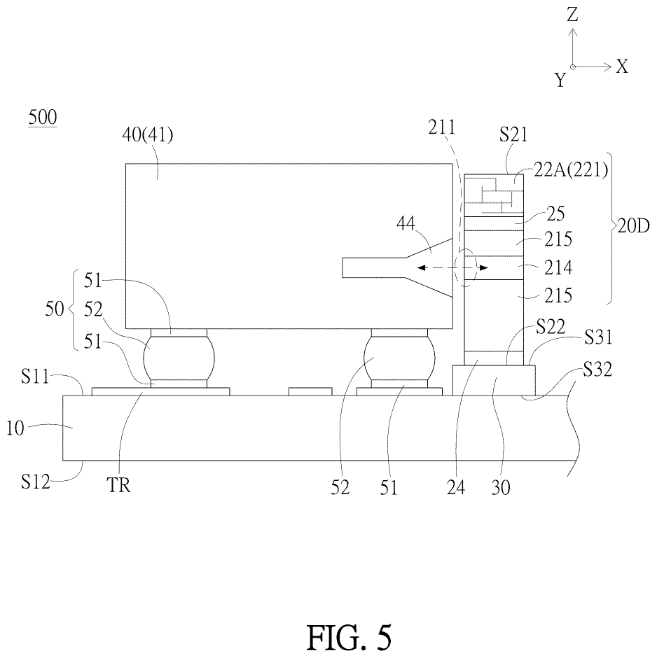

Referring to FIG. 5, the structure of the module structure 500 is similar to the module structure 400 in FIG. 4, the major difference therebetween is that the patterned optical layer 21A is arranged between the patterned conductive layer 22A and the patterned adhesive layer 30 in the patterned stack structure 20D of the module structure 500.

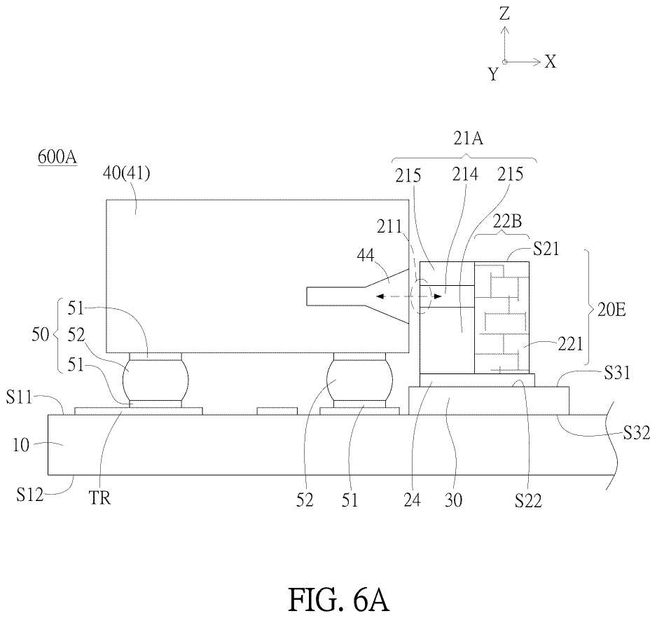

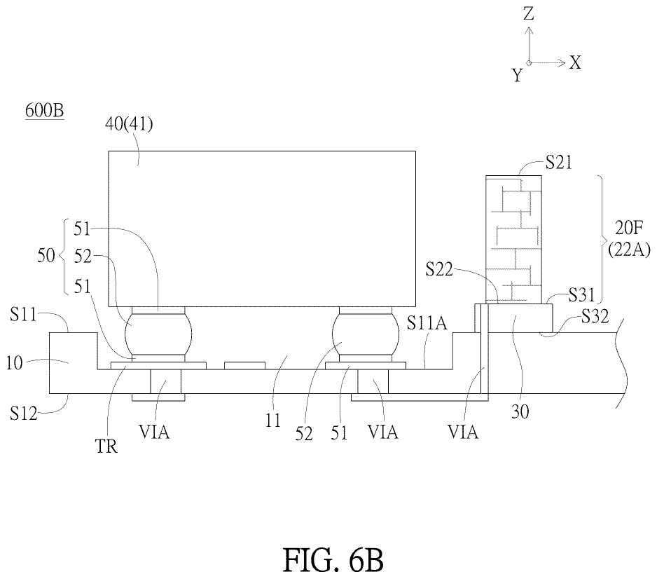

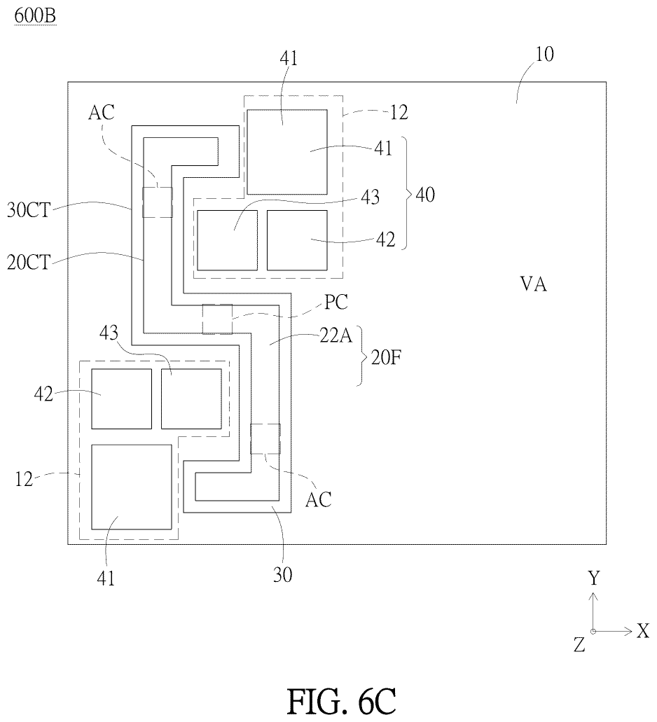

Referring to FIG. 6A, the structure of the module structure 600 is also similar to the module structures 400, 500, and the major difference therebetween is that, the patterned optical layer 21A and the patterned conductive layer 22B are arranged in a coplanar manner in the patterned stack structure 20E of the module structure 600. For example, both of the patterned optical layer 21A and the patterned conductive layer 22B are arranged on the base material 24 in FIG. 6A, but is not limited there to; in other cases, both of them can also arranged on the patterned adhesive layer 30.

Referring to FIGS. 6B and 6C, the module structure 600B further defines one or more recesses 11 distributed on areas of the first surface S11 of the substrate 10, however, the patterned stack structure(s) 20F does not arrange in the recess(es) 11. The bottom surface S11A of the recess 11 can be considered as a part of the first surface S11 of the substrate 10, the recess 11 similarly serves as the first surface S11 of the substrate 10. The semiconductor component 40 can be arranged in the corresponding recess 11, and this design can reduce the height difference between the semiconductor component 40 and the patterned stack structure 20F. In this case, the patterned conductive structure 20F only comprises the patterned conductive layer 22A, but is not limited thereto; the patterned stack structure 20 in this structure comprises more types, for example the patterned stack structure 20 of the module structure 600B can further comprises the patterned optical layer (not shown in the FIG. 6B). Since the semiconductor component 40 is arranged in the recess 11, and the patterned stack structure (especially the patterned optical layer) is arranged on the non recess region of the substrate 10, the thickness of the cladding layer or the optical reflection layer of the patterned optical layer can be reduced when coupled to the semiconductor component. Referring to FIG. 6C, the patterned conductive layer 22A of the module structure 600B further includes one or both of an active-component AC and a passive-component unit PC. The active-component AC includes but is not limited to TFT (thin film transistor), the passive-component PC includes but is not limited to IPD (integrated passive device), both of which can be fabricated by thin film process.

Referring to FIG. 7, the module structure 700 further defines one or more vacant areas VA distributed on the first surface S11 of the substrate 10, the vacant area VA is the area of the first surface S11 where no patterned stack structure 20 is arranged thereon. The distribution area of the patterned stack structure 20 in this figure is broader. Furthermore, a plurality of semiconductor components 40 are arranged on the first surface S11 of the substrate 10, and at the one or more vacant areas VA. The plurality of the semiconductor components 40 can be optically and/or electrically coupled to the patterned stack structure 20, and two of the semiconductor components 40 can communicate with each other by either one or both of electrical signals and optical signals.

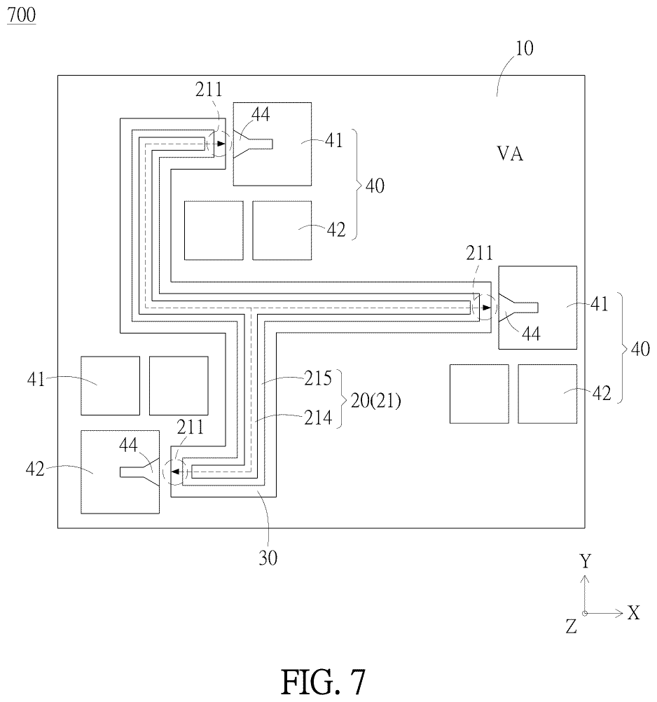

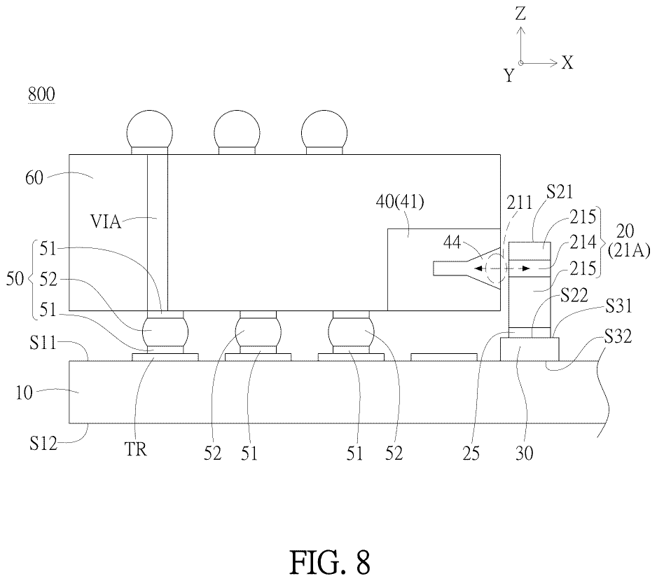

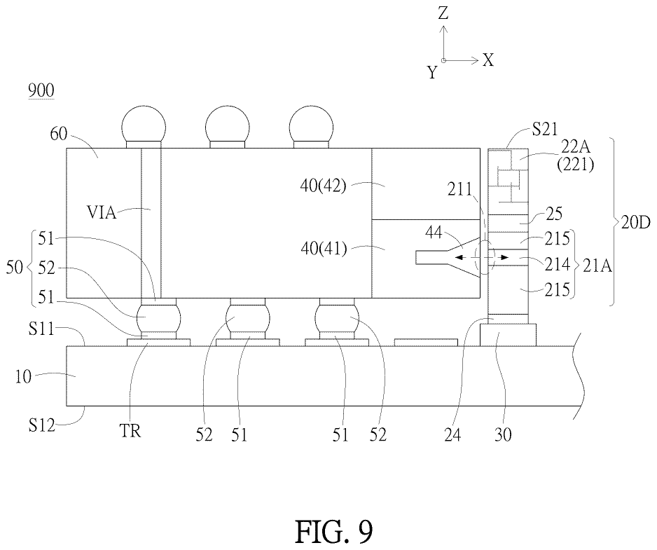

Referring to FIGS. 8 and 9, the module structures 800, 900 further include an interposer 60, and the semiconductor component 40 is arranged on or in the interposer 60. The semiconductor component 40 in FIG. 8 includes a photonic integrated circuit (PIC) 41, while the semiconductor component 40 in FIG. 9 includes both a photonic integrated circuit (PIC) 41 and an electronic integrated circuit (EIC) 42, but is not limited thereto. The first surface S11 of the substrate 10 can be provided with a plurality of the conductive pads 51, and the interposer 60 is electrically connected to the conductive pads 51 by the conductive material 52. The interposer 60 further includes one or more through holes VIA and the through holes VIA can be served as conductive holes, but is not limited thereto.

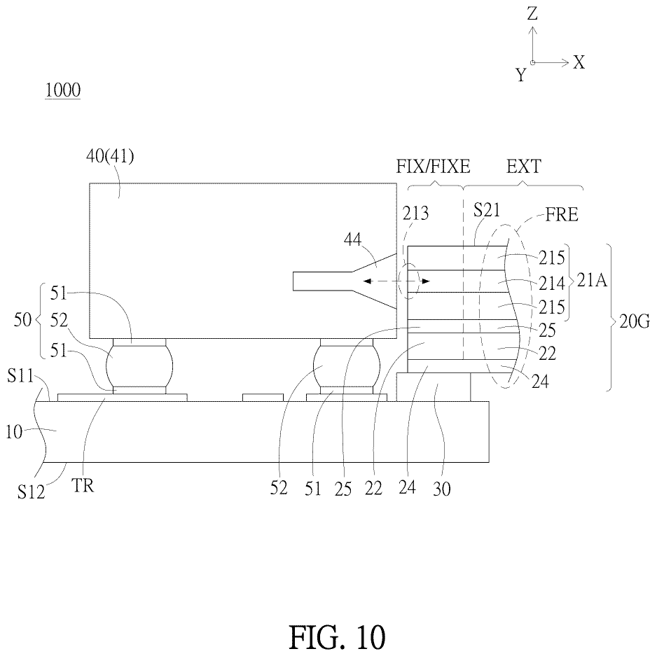

Referring to FIG. 10, the module structure 1000 also comprises the substrate 10, the patterned stack structure 20, the patterned adhesive layer 30 and the semiconductor component 40. The whole structure thereof is similar to the abovementioned cases, and the major difference therebetween is that the patterned stack structure 20G comprises a fixed portion FIX and an extension portion EXT, the fix portion FIX is the portion of the patterned stack structure 20G bonded to the patterned adhesive layer 30, and the extension portion EXT is the portion of the patterned stack structure 20 not bonded to the patterned adhesive layer 30. In addition, the side of the patterned stack structure 20G boded to the patterned adhesive layer 30 is defined as a fixed end FIXE, and the side thereof at the extension portion EXT is defined as a free end FRE. Along the direction Z perpendicular to the first surface S11 of the substrate 10, a projection of the free end FRE of the patterned stack structure 20G is extended beyond a projection of a side of the substrate 10. The patterned stack structure 20G also comprises the patterned optical layer 21A and the patterned conductive layer 22. In some cases, the patterned conductive layer 22 can be a fang-out structure, and the line space of the traces arranged near the fixed end FIXE is less than the line space of the traces arranged near the free end FRE.

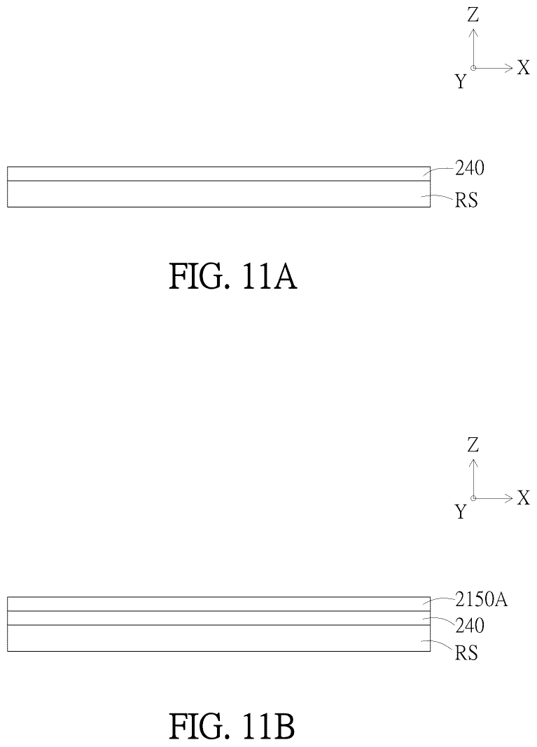

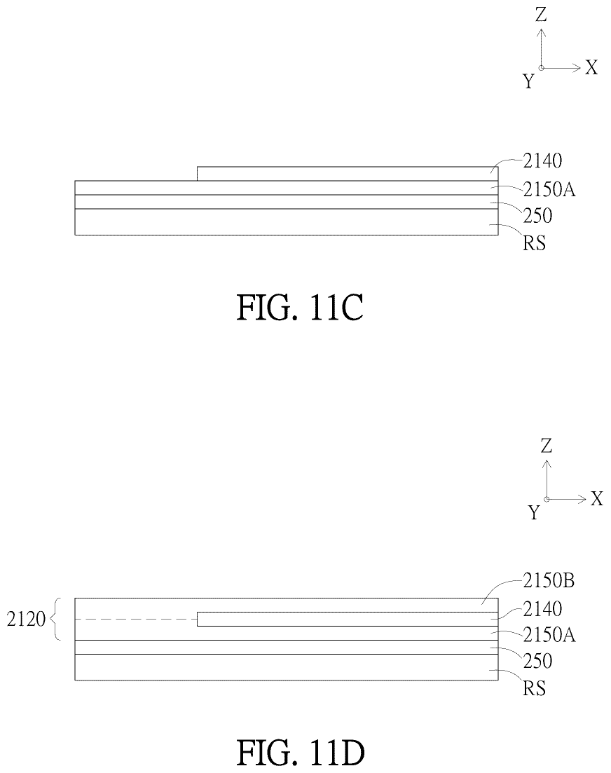

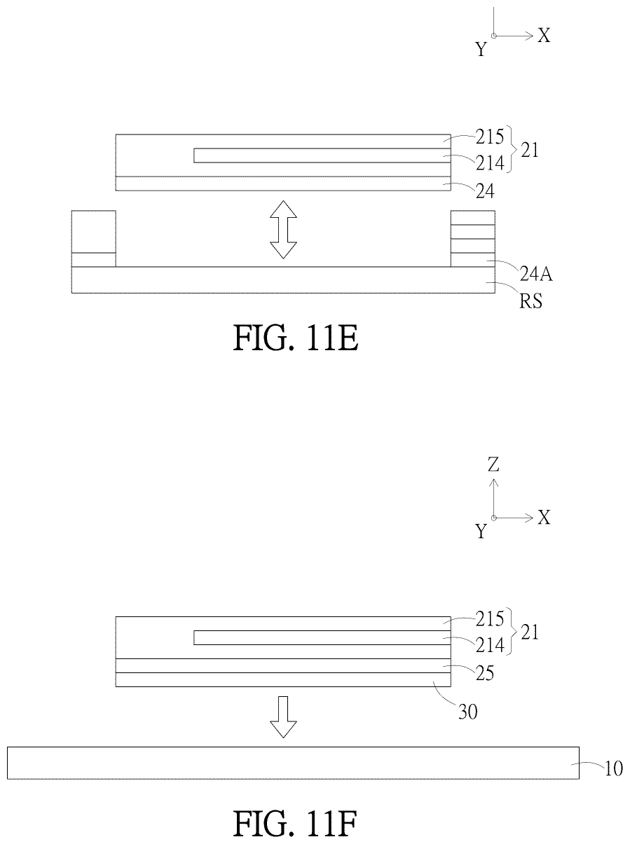

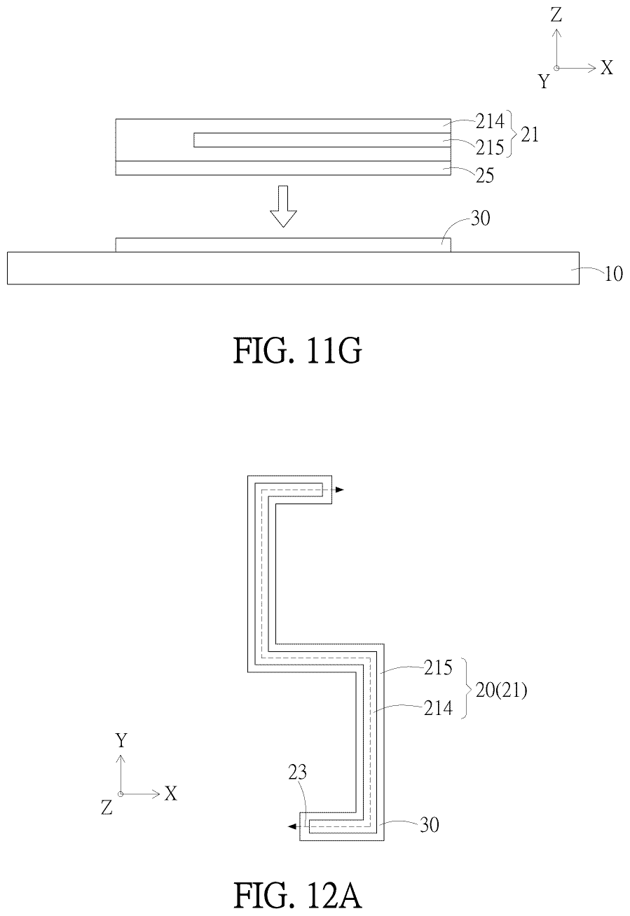

Referring to FIGS. 11A to 11G provide a fabrication method of this invention. In this method, the patterned stack structure 20 comprises the patterned optical layer 21A, and the patterned optical layer 21A comprises an optical waveguide. FIG. 11A discloses a dual-layered substrate structure in which a flexible substrate 240 disposed on a rigid substrate RS, and both of the rigid substrate RS and the flexible substrate 240 are non-patterned substrate. The flexible substrate 240 can be directly or indirectly bonded to the rigid substrate RS. One example of indirectly bonding is that the flexible substrate 240 is bonded to the rigid substrate RS by a very thin adhesive layer, In addition, the flexible substrate 240 can be a polyimide substrate, but is not limited thereto. Next, as shown in FIG. 11B, a reflection layer 2150A is arranged on the flexible substrate 240 in FIG. 11A; and an optical transmission layer 2140 is arranged along the reflection layer 2150A as shown in FIG. 11C. Another reflection layer 2150B is then arranged above the reflection layer 2150A and the optical transmission layer 2140, making the optical transmission layer 2140 is completely encapsulate by the reflection layer 2150 to form an integrated structure.

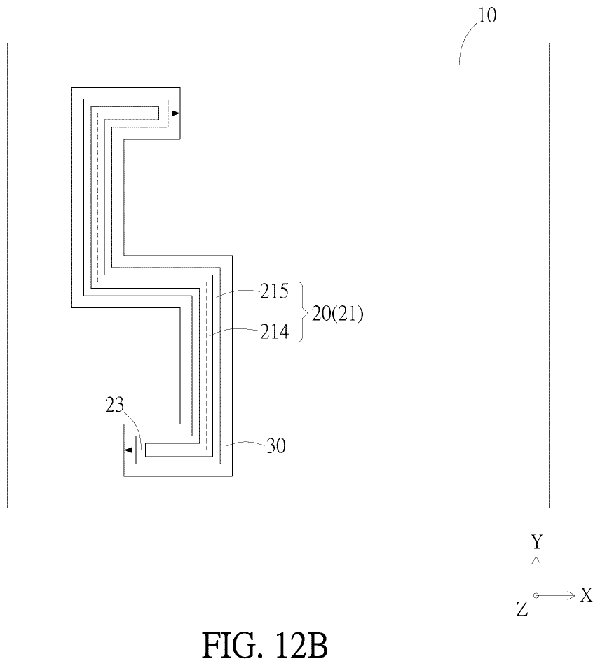

One method of fabricating the patterned optical layer 21 is that, in any state in FIG. 11B to FIG. 11D, patterning the reflection layer 2150 and its optical transmission layer 2140; for example, in FIG. 11B, the reflection layer 2150A partially arranged on the flexible substrate 240 can be a patterned reflection layer 2150A; in another case, the reflection layer 2150B in FIG. 11B is non-patterned, and being patterned by other processes in the steps shown in FIG. 11C or FIG. 11D. In conclusion, the reflection layer 2150 and the optical transmission layer 2140 encapsulated thereby, are already patterned before the steps shown in FIG. 11A. The process shown in FIG. 11E is removing the patterned optical layer 21 comprising the reflection layer 215 and the optical transmission layer 214 from the structure shown in FIG. 11D by laser lift-of. Another method of fabricating the patterned optical layer 21 is that, in any state from FIG. 11B to FIG. 11D, both the reflection layer 2150 and the optical transmission layer 2140 encapsulated thereby remain non-patterned, the laser lift-off process and a patterning process are performed simultaneous to the reflection layer 2150 and the optical transmission layer 2140 to form the patterned optical layer 21 comprising the reflection layer 215 and the optical transmission layer 214 in the step shown in FIG. 11E. In both of the abovementioned methods, after the step of FIG. 11E is completed, a temporary structure as shown in FIG. 12A is obtained.

As shown in FIG. 11F, an adhesive layer is directly bonded to one side of the patterned optical layer 21 to form a patterned adhesive layer 30, then the patterned adhesive layer 30 bonds the patterned optical layer 21 to the substrate 10; at this time, the contour of the patterned adhesive layer 30 is the same as the contour of the patterned optical layer 21. FIG. 11G discloses another method to bond the patterned optical layer 21 to the substrate. In this method, the adhesive layer is first bonded to one side of the substrate 10, and then the patterned optical layer 21 is bonded to the adhesive layer and subsequently to the substrate 10. The patterned adhesive layer 30 in FIG. 11F or FIG. 11G can be formed after the adhesion layer is bonded to the substrate 10, or after the patterned optical layer 21 is bonded to the substrate 10; at this time, the contour of the patterned adhesive layer 30 can be the same as or slightly larger than the contour of the patterned optical layer 21.

After the step shown in FIG. 11G is completed, another temporary structure as shown in FIG. 12B is obtained. Then, the semiconductor component(s) 40, or other active components, passive components can be arranged at other areas on the first surface S11 of the substrate 10, to obtain the module structure of this invention as shown in FIG. 1A.

Based on the above description, it should be understood that various embodiments of the disclosure have been described in the specification for illustrative purposes, and various modifications can be made without departing from the scope and spirit of the disclosure. Therefore, the various embodiments of the disclosure are not intended to limit the true scope and spirit of the invention.

The above descriptions are exemplary rather than restrictive. Any equivalent modifications or changes made without departing from the spirit and scope of this invention should be included in the appended patent claims.

What is claimed is:

1. A module structure, comprising:
a substrate, defining a first surface and a second surface opposite to each other;
a patterned stack structure, arranged on the first surface of the substrate; wherein the patterned stack structure includes one or both of a patterned optical layer and a patterned conductive layer for transmitting either one or both of electrical signals and optical signals;
a patterned adhesive layer arranged between the substrate and the patterned stack structure; and
a semiconductor component, disposed on the first surface of the substrate, coplanar with the patterned stack structure and the patterned adhesive layer, and coupled to the patterned adhesive layer.

2. The module structure of claim 1, wherein the patterned stack structure defines a stack-structure contour which is defined by laser-cutting.

3. The module structure of claim 1, wherein the substrate defines a coverage ratio of the patterned stack structure, and the coverage ratio is not greater than 50%.

4. The module structure of claim 1, wherein the patterned adhesive layer defines a first surface and a second surface opposite to each other, the first surface connects to the patterned stack structure, the second surface connects to the substrate; and a surface roughness of the first surface is less than a surface roughness of the second surface.

5. The module structure of claim 1, wherein the patterned stack structure includes a base material, and the patterned optical layer and/or the patterned conductive layer are configured on the base material.

6. The module structure of claim 1, wherein the base material includes at least one material of polyimide and resin.

7. The module structure of claim 1, wherein the patterned stack structure includes the patterned optical layer, and the patterned optical layer and the semiconductor component each have an optical port that are optically coupled to each other.

8. The module structure of claim 7, wherein the patterned optical layer defines a first surface and a second surface opposite to each other, and a side edge connecting the first and second surfaces, wherein the optical port is disposed at the side edge of the patterned optical layer.

9. The module structure of claim 7, wherein the semiconductor component defines a first surface and a second surface opposite to each other, and a side edge connecting the first and second surfaces, wherein the optical port is disposed at the side edge of the semiconductor component.

10. The module structure of claim 1, wherein the first surface of the substrate is configured with a plurality of conductive pads, and the semiconductor component is electrically connected to the conductive pads.

11. The module structure of claim 1, wherein the semiconductor component includes at least one of an electronic integrated circuit (EIC), a photonic integrated circuit (PIC), a graphics processing unit (GPU), a central processing unit (CPU), an application-specific integrated circuit (ASIC), and a switch.

12. The module structure of claim 1, further including an interposer, wherein the semiconductor component is configured to the interposer.

13. The module structure of claim 12, wherein the first surface of the substrate is configured with a plurality of conductive pads, and the interposer is electrically connected to the conductive pads.

14. The module structure of claim 1, wherein the patterned stack structure includes the patterned conductive layer, the patterned conductive layer includes one or more conductive traces, and at least a portion of the conductive traces has a trace space no greater than 50 μm.

15. The module structure of claim 1, wherein the patterned stack structure includes the patterned conductive layer, the patterned conductive layer includes one or more conductive traces, and at least a portion of the conductive traces has a thickness no greater than 20 μm.

16. The module structure of claim 1, wherein the substrate includes a single-layer or multi-layer substrate having at least one material of silicon or silicon-containing material, glass, resin, ceramic, glass ceramic, polyimide, bismaleimide triazine (BT), or glass-reinforced epoxy laminate (FR4).

17. The module structure of claim 16, wherein the substrate includes at least one of a low-temperature co-fired ceramic (LTCC) substrate, a mid-temperature co-fired ceramic (MTCC) substrate, and a high-temperature co-fired ceramic (HTCC) substrate.

18. The module structure of claim 1, wherein the substrate has a recess on the first surface, and the semiconductor component is configured in the recess.

19. A module structure, comprising:
a substrate, defining a first surface and a second surface opposite to each other;
a patterned stack structure, partially arranged on the first surface of the substrate; wherein the patterned stack structure includes one or both of a patterned optical layer and a patterned conductive layer;
a patterned adhesive layer, arranged between the substrate and the patterned stack structure, transmitting either one or both of electrical signals and optical signals;
one or more vacant areas distributed on areas of the first surface of the substrate where the patterned stack structure is absent; and
a plurality of semiconductor components, arranged on the first surface of the substrate and located at the one or more vacant areas; wherein the semiconductor components are coplanar with the patterned adhesive layer and the patterned stack structure, and coupled to the patterned stack structure.

20. The module structure of claim 19, wherein two of the semiconductor components communicate with each other by either one or both of electrical signals and optical signals.
